(19) United States
(12) Patent Application Publication
(10) Pub. No.: US 2026/0188398 A1
(43) Pub. Date: Jul. 2, 2026

(54) DETECTING COMPLETE PROGRAMMING IN ALL LEVEL PROGRAMMING

(71) Applicant: Micron Technology, Inc., Boise, ID (US)

(72) Inventors: Murong Lang, San Jose, CA (US); Zhenming Zhou, San Jose, CA (US); Hanping Chen, San Jose, CA (US); Jun Wan, San Jose, CA (US)

(21) Appl. No.: 19/003,538

(22) Filed: Dec. 27, 2024

(51) Int. Cl. G11C 16/34; G11C 16/26

(52) U.S. Cl. CPC G11C 16/3459; G11C 16/26; G11C 16/3404

(57) ABSTRACT

A system and method for reading data from a memory device. The system and method determine that a power loss event has occurred during an all-level program operation of the memory device, the all-level program operation simultaneously programming multiple levels of the memory device. The system and method, in response to determining that the power loss event has occurred during the all-level program operation of the memory device, perform a read operation of an individual portion of the memory device using an individual read level to detect incomplete programming across the multiple levels and detect incomplete programming based on determining that a read bit error rate (RBER) associated with the read operation of the individual portion transgresses a threshold.

### TECHNICAL FIELD

This disclosure relates generally to memory sub-systems and, more specifically, to providing adaptive media management for memory components, such as memory dies.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The disclosure will be understood more fully from the detailed description given below and from the accompanying drawings of various examples of the disclosure. The drawings, however, should not be taken to limit the disclosure to the specific examples, but are for explanation and understanding only.

FIG. 1 is a block diagram illustrating an example computing system that includes a memory sub-system, in accordance with some examples.

FIG. 2 is a block diagram of example inner and boundary word line (WL) read level offset tables, in accordance with some examples.

FIG. 3 is a block diagram of an example of applying an adjusted boundary WL read level offset to read data from a WL, in accordance with some examples.

FIG. 4 illustrates memory levels during an all-level program (ALP) sequence, in accordance with some examples.

FIG. 5 illustrates a diagram of operations performed using the media operations manager, in accordance with some examples.

FIG. 6 is a block diagram of an example computer system, in accordance with some examples.

### DETAILED DESCRIPTION

The present disclosure configures a system component, such as a memory sub-system controller to perform NAND Detect Program Completion (NDPC) process for ALP operations of a memory device. Specifically, the controller can determine that a power loss event has occurred during an ALP operation where multiple levels are being programmed simultaneously. In such cases, the controller performs read operations of an individual portion of the memory device, such as a partial block (PB), using an individual read level, such as upper page read level (or any other suitable level) to detect incomplete programming. The individual read level can be generated/computed using PB boundary word line (WL) offsets. For example, the controller can generate the PB boundary WL offset to read the individual portion using one of two different approaches. The controller can use a PB lookup table with boundary WL offsets or can apply a low VpassR with specialized boundary WL offsets. The controller can measure a read bit error rate (RBER) of the individual read level of the individual portion to determine whether cells (including the cells of the individual read level and other levels, such as upper page, extra page, and/or lower page) in the individual portion have reached their intended threshold voltage levels during the simultaneous ALP operation. The approach provides increased sensitivity through the use of three read level strobes for upper page reading and offers flexibility to add additional lower page and extra page read operations to verify program completion status.

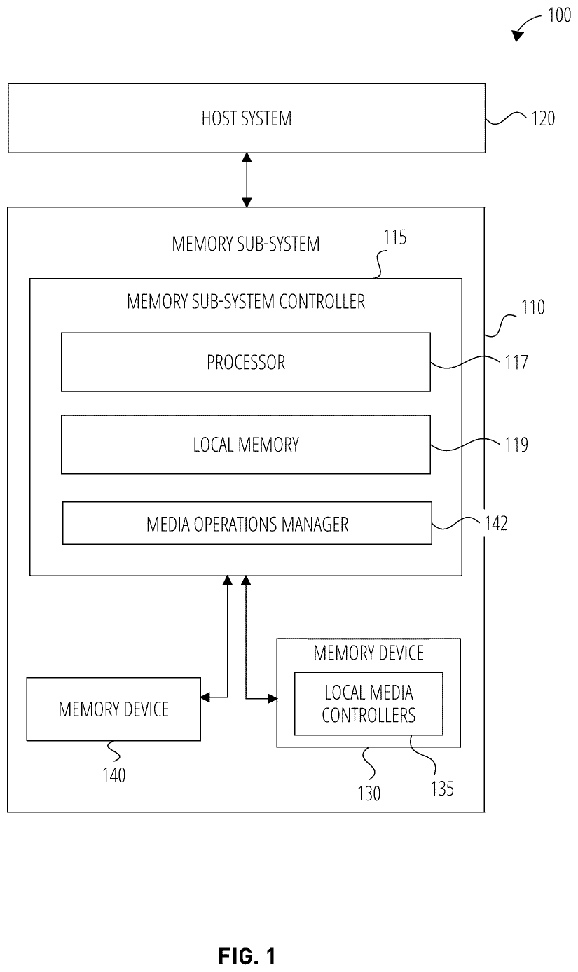

A memory sub-system can be a storage device, a memory module (memory component), or a hybrid of a storage device and memory module. Examples of storage devices and memory modules are described below in conjunction with FIG. 1. In general, a host system can utilize a memory sub-system that includes one or more memory components, such as memory devices (e.g., memory dies or planes across multiple memory dies) that store data. The host system can send access requests (e.g., write command, read command) to the memory sub-system, such as to store data at the memory sub-system and to read data from the memory sub-system. The data (or set of data) specified by the host is hereinafter referred to as “host data,” “application data,” or “user data.”

The memory sub-system can initiate media management operations, such as a write operation, on host data that is stored on a memory device. In some examples, firmware of the memory sub-system may re-write previously written host data from a location on a memory device to a new location as part of garbage collection management operations. The data that is re-written, for example as initiated by the firmware, is hereinafter referred to as “garbage collection data.” “User data” can include host data and garbage collection data. “System data” hereinafter refers to data that is created and/or maintained by the memory sub-system for performing operations in response to host requests and for media management. Examples of system data include, and are not limited to, system tables (e.g., logical-to-physical address mapping table), data from logging, scratch pad data, etc.

Many different media management operations can be performed on the memory device. For example, the media management operations can include different scan rates, different scan frequencies, different wear leveling, different read disturb management, different near miss error correction code (ECC), and/or different dynamic data refresh. Wear leveling ensures that all blocks in a memory component approach their defined erase-cycle budget at the same time, rather than some blocks approaching it earlier. Read disturb management counts all of the read operations to the memory component. If a certain threshold is reached, the surrounding regions are refreshed. Near-miss ECC refreshes all data read by the application that exceeds a configured threshold of errors. Dynamic data-refresh scan reads all data and identifies the error status of all blocks as a background operation. If a certain threshold of errors per block or ECC unit is exceeded in this scan-read, a refresh operation is triggered.

A memory device can be a non-volatile memory device. A non-volatile memory device is a package of one or more dice (or dies). Each die can be comprised of one or more planes. For some types of non-volatile memory devices (e.g., NAND devices), each plane is comprised of a set of physical blocks. For some memory devices, blocks are the smallest areas that can be erased. Such blocks can be referred to or addressed as logical units (LUN). Each block is comprised of a set of pages. Each page is comprised of a set of memory cells, which store bits of data. The memory devices can be raw memory devices (e.g., NAND), which are managed externally, for example, by an external controller. The memory devices can be managed memory devices (e.g., managed NAND), which is a raw memory device combined with a local embedded controller for memory management within the same memory device package.

There are challenges in efficiently managing or performing media management operations on typical memory devices. Specifically, certain memory devices, such as NAND flash devices, store data in different WLs. The memory devices can program data into different blocks. Memory blocks that are fully programmed and are closed are referred to as full blocks (FBs). Memory blocks that are not fully programmed (e.g., are still open and have one or more sub-blocks that remain empty and ready to be programmed) are referred to as PBs. In order to reduce read disturb errors and other extrinsic defect related errors when reading data, the controllers can apply offsets to the read threshold voltages used to read data from FBs and PBs. Specifically, when reading data from PBs, the controllers can either apply inner WL offsets or boundary WL offsets depending on whether the WL being read includes a last written page (LWP) or not.

In some cases, the controller can keep track of which regions of the memory components were last programmed. Namely, the controller can store an indicator of the location of the last page that was programmed to the set of memory components. The WL that includes the last page that was programmed can be referred to as a boundary WL. All other WLs that do not include the last page can be referred to as inner WLs.

In conventional systems using ISPP (Incremental Step Pulse Programming), multi-level memory cells (e.g., in multi-level cell (MLC), tri-level cell (TLC), and/or quad-level cell (QLC) memory devices) are programmed level-by-level. Namely, lower levels are programmed first, and higher levels are programmed last. During this process, if a power loss occurs (e.g., an asynchronous power loss event (APL)), the highest level (e.g., Level 7) is most likely to be distorted (or contain an RBER that exceeds an error rate threshold) since the highest level is programmed last. The conventional NDPC process is specifically designed to detect this pattern in the LWP by computing a read level for Level 3 at the valley center to minimize extra page false bit count contribution and computing the Level 7 read level at the edge for higher sensitivity detection. This approach works effectively because in ISPP, when power loss occurs during programming, the lower levels are already properly programmed while the higher levels may be incomplete. So, if the RBER of data stored in Level 7 of the LWP exceeds a threshold, the memory controller may determine that the LWP or PB has not been completely programmed before the power loss occurred. In such cases, the controller may reprogram that page or perform other error correction operations.

ALP represents a fundamentally different approach to programming NAND memory cells. Instead of programming levels sequentially, ALP simultaneously programs all levels (e.g., Levels 0-7 in TLC memory devices) by applying different bit line biases to achieve different boosting potentials (Vpillar) for each memory cell. ALP uses a single program voltage pulse while controlling individual channel potentials to reach different threshold voltages for different cells simultaneously. ALP may require only 4-6 pulses to complete programming, compared to ISPP's 10-15 pulses. During each pulse, ALP programs cells to roughly their target positions across all levels at once, then uses subsequent pulses to fine-tune the threshold voltage distributions.

The conventional NDPC process cannot work effectively for ALP because when a power loss occurs during ALP operations, all levels are potentially incomplete or distorted, not just the highest level. Since ALP programs all levels simultaneously using different channel potentials and a single gate bias voltage, a power loss during programming means cells across all levels may not have reached their intended threshold voltages. This fundamental difference necessitates a new approach to NDPC detection. Particularly, conventional NDPC processes cannot be applied to memory devices programmed using the ALP process to identify incomplete programming. This is because conventional NDPC processes rely on detecting distortion specifically in Level 7 by placing Level 3 at the valley center and Level 7 at the edge for sensitivity, which assumes a sequential level-by-level programming approach where lower levels are already properly programmed. However, in ALP, the programming process uses different channel potentials and boosting voltages to simultaneously program all levels, meaning a power loss can result in incomplete programming across any or all levels rather than just the highest level. Additionally, since ALP uses different bit line biases and channel potentials for each level to achieve different boosting potentials in a single pulse, the conventional method of detecting distortion at a specific level cannot accurately capture the program completion status when all levels are programmed concurrently with varying channel voltages.

The present disclosure addresses these technical challenges by providing a memory sub-system controller (memory controller) that can detect incomplete programming across all levels during ALP operations by performing upper page read operations with partial block boundary WL offsets. The memory controller implements a novel NDPC detection approach that uses default upper page read levels involving three read level strobes to provide increased sensitivity for detecting incomplete programming across multiple threshold voltage levels. Additionally, the memory controller provides flexibility to add lower page and extra page read operations for further verification and can implement two different PB handling approaches either using a PB lookup table with boundary WL offsets or applying a low VpassR with specialized boundary WL offsets. This approach effectively addresses the challenges of detecting program completion in ALP operations where all levels are programmed simultaneously using different channel potentials and boosting voltages, rather than the conventional level-by-level programming approach.

In some cases, the memory controller can determine that a power loss event has occurred during an ALP operation where multiple levels are being programmed simultaneously. In such cases, the controller performs read operations of an individual portion of the memory device, such as a PB, using an individual read level, such as upper page read level (or any other suitable level) to detect incomplete programming. The individual read level can be generated/computed using PB boundary WL offsets. The controller can measure a RBER of the individual read level of the individual portion to determine whether cells (including the cells of the individual read level and other levels, such as upper page, extra page, and/or lower page) in the individual portion have reached their intended threshold voltage levels during the ALP operation. This approach provides increased sensitivity through the use of three read level strobes for upper page reading and offers flexibility to add additional lower page and extra page read operations to verify program completion status.

In some examples, a memory system can be configured to detect incomplete programming during ALP operations through various approaches. In some implementations, the system includes a memory device and processing device that work together to detect power loss events during ALP operations where multiple levels are programmed simultaneously. When such a power loss is detected, the controller can perform read operations using specific read levels to identify incomplete programming and can determine program completion status based on whether the RBER exceeds defined thresholds.

In some examples, the ALP operation works by applying different channel potentials to different memory cells to achieve varying voltage differentials between the gate voltage and respective channel potentials. The controller then uses verify operations to tighten the threshold voltage distributions for each programming level. In some circumstances, the controller can perform reads on the LWP using upper page read levels, where the RBER indicates distortion across multiple levels when power loss occurs before programming completes. The memory device may be implemented as various types of multi-level storage, including MLC, TLC, or QLC configurations, and can handle APL events.

In some implementations involving PBs with multiple WLs, the controller may apply a low pass read voltage to empty WLs while using modified boundary WL offset tables specifically configured for the low pass read voltage scenario. Alternatively, the controller may utilize separate inner and boundary WL offset tables, storing different sets of read level offsets for different WL types. In some cases, the controller can perform read operations by combining offsets from different tables-using one offset for inner WL and generating combined offsets for boundary WLs. The controller can maintain a buffer to track the last programmed region and determine PB status. Additionally, the controller may perform supplementary read operations on lower pages (LP) or extra pages (XP) to verify program completion status, with adjustable read levels to increase detection sensitivity.

The controller can adapt its approach based on whether PB handling uses lookup tables or low VpassR mode, selecting appropriate boundary WL offsets accordingly. These operations form part of a comprehensive NDPC process specifically designed to verify programming completion status after power loss events in 3D NAND devices.

Though various examples are described herein as being implemented with respect to a memory sub-system (e.g., a controller of the memory sub-system), some or all of the portions of an embodiment can be implemented with respect to a host system, such as a software application or an operating system of the host system.

FIG. 1 illustrates an example computing system 100 that includes a memory sub-system 110, in accordance with some examples. The memory sub-system 110 can include media, such as one or more volatile memory devices (e.g., memory device 140), one or more non-volatile memory devices (e.g., memory device 130), or a combination of such.

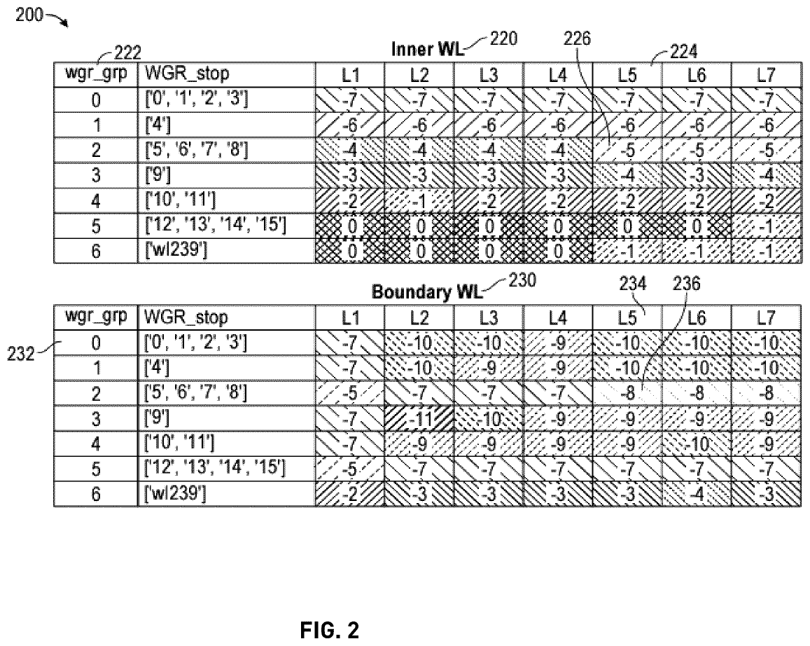

In some examples, a memory or register (e.g., included as part of the local memory 119) can store an inner WL offset table and a boundary WL offset table. In some cases, the inner WL offset table and the boundary WL offset table can be combined into a single table. For example, as shown in diagram 200 of FIG. 2, the inner WL offset table 220 can store various read level offsets that can be applied to a read threshold voltage when reading one or more inner WLs. Namely, a first WL or WLG 222 can be associated with a first set of read level offsets 224. Each read level offset in the first set of read level offsets 224 can represent a different amount of offset to apply to the read threshold voltage when reading different levels of TLC storage (or other multi-level cell storage). Namely, when reading level 1 from the TLC storage in a first WLG (e.g., word line group 4), a-2 DAC offset can be applied, when reading level 2 from the TLC storage in the first WLG, a-1 DAC offset can be applied, and when reading levels 3-7 from the TLC storage in the first WLG, a-2 DAC offset can be applied. A second WL or WLG 222 can be associated with a second set of read level offsets 224. Each read level offset in the second set of read level offsets 224 can represent a different amount of offset to apply to the read threshold voltage when reading different levels of TLC storage (or other multi-level cell storage). Namely, when reading levels 1-4 from the TLC storage in the second WLG (e.g., word line group 6), and when reading levels 5-7 from the TLC storage in the second WLG, a-1 DAC offset can be applied.

The boundary WL offset table 230 can store various read level offsets that can be applied to a read threshold voltage when reading one or more boundary WLs (e.g., WLs that include a last programmed portion or LWP). Namely, the first WL or WLG 232 can be associated with a second set of read level offsets 234. Each read level offset in the third set of read level offsets 234 can represent a different amount of offset to apply to the read threshold voltage when reading different levels of TLC storage. These offsets can be the same or different from those mentioned with respect to the inner WL offset table 220. For example, the read level offset 226 in the inner WL offset table 220 for a particular WL and for a particular level of the TLC storage can be a first value of −5 DAC. The read level offset 236 in the boundary WL offset table 230 for the same particular WL and for the same particular level of the TLC storage can be a second value of −8 DAC.

In some cases, the media operations manager 142 determines that the request to read the portion of the set of memory components corresponds to a PB. In such cases, the media operations manager 142 can access a buffer or storage to identify which WL is indicated to store the last programmed portion or LWP. The media operations manager 142 can determine a level of the TLC storage that is being read and retrieves the read level offset stored in the inner WL offset table 220. The media operations manager 142 obtains a read threshold voltage for reading data from the portion and modifies the read threshold voltage by the read level offset retrieved from the inner WL offset table 220. The media operations manager 142 can then read each inner WL of the PB using the same modified read threshold voltage. Namely, the media operations manager 142 can read each WL of the PB excluding the identified WL that includes the last programmed portion or LWP using the read threshold voltage that has been modified by the corresponding value in the inner WL offset table 220.

The media operations manager 142 can obtain the read level offset stored in the boundary WL offset table 230 for the read level being read from the identified WL that includes the last programmed portion or LWP. The media operations manager 142 can combine (e.g., add) the read level offset stored in the boundary WL offset table 230 with the read level offset that was used to read the inner WL to generate a second read level offset. In some cases, a table (a separate table) can be maintained that includes the already combined values so that the media operations manager 142 does not have to combine the read level offset stored in the boundary WL offset table 230 with the read level offset that was used to read the inner WL to generate the second read level offset (e.g., the second read level offset can be precomputed and stored in a table). The media operations manager 142 can then read the identified WL of the PB that includes the last programmed portion or LWP using the read threshold voltage adjusted by the second read level offset.

Referring back to FIG. 1, a memory sub-system 110 can be a storage device, a memory module, or a hybrid of a storage device and memory module. Examples of a storage device include a solid-state drive (SSD), a flash drive, a universal serial bus (USB) flash drive, a secure digital (SD) card, an embedded Multi-Media Controller (eMMC) drive, a Universal Flash Storage (UFS) drive, and a hard disk drive (HDD). Examples of memory modules include a dual in-line memory module (DIMM), a small outline DIMM (SO-DIMM), and various types of non-volatile dual in-line memory module (NVDIMM).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some examples, the host system 120 is coupled to different types of memory sub-systems 110. FIG. 1 illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, and the like.

The host system 120 can include a processor chipset and a software stack executed by the processor chipset. The processor chipset can include one or more cores, one or more caches, a memory controller (e.g., NVDIMM controller), and a storage protocol controller (e.g., a peripheral component interconnect express (PCIe) controller, serial advanced technology attachment (SATA) controller). The host system 120 uses the memory sub-system 110, for example, to write data to the memory sub-system 110 and read data from the memory sub-system 110.

The host system 120 can include or be coupled to the memory sub-system 110 so that the host system 120 can read data from or write data to the memory sub-system 110. The host system 120 can be coupled to the memory sub-system 110 via a physical host interface. Examples of a physical host interface include, but are not limited to, a serial advanced technology attachment (SATA) interface, a peripheral component interconnect express (PCIe) interface, a compute express link (CXL) interface, a universal serial bus (USB) interface, a Fibre Channel interface, a Serial Attached SCSI (SAS) interface, etc. The physical host interface can be used to transmit data between the host system 120 and the memory sub-system 110. The host system 120 can further utilize an NVM Express (NVMe) interface to access the memory devices 130, 140 when the memory sub-system 110 is coupled with the host system 120 by the PCIe or CXL interface. The physical host interface can provide an interface for passing control, address, data, and other signals between the memory sub-system 110 and the host system 120.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include a NAND flash memory and write-in-place memory, such as a 3D cross-point memory device, which is a cross-point array of non-volatile memory cells. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional (2D) NAND and 3D NAND.

Each of the memory devices 130, 140 can include one or more arrays of memory cells. One type of memory cell, for example, single level cells (SLCs), can store one bit per cell. Other types of memory cells, such as multi-level cells (MLCs), tri-level cells (TLCs), quad-level cells (QLCs), and penta-level cells (PLCs), can store multiple bits per cell. In some examples, each of the memory devices 130, 140 can include one or more arrays of memory cells such as SLCs, MLCs, TLCs, QLCs, or any combination of such. In some examples, a particular memory device can include an SLC portion, and an MLC portion, a TLC portion, or a QLC portion of memory cells. The memory cells of the memory devices 130, 140 can be grouped as pages that can refer to a logical unit of the memory device used to store data. With some types of memory (e.g., NAND), pages can be grouped to form blocks or BSs. As used herein, a block comprising SLCs can be referred to as a SLC block, a block comprising MLCs can be referred to as a MLC block, a block comprising TLCs can be referred to as a TLC block, and a block comprising QLCs can be referred to as a QLC block.

Although non-volatile memory components such as NAND-type flash memory (e.g., 2D NAND, 3D NAND) and 3D cross-point array of non-volatile memory cells are described, the memory device 130 can be based on any other type of non-volatile memory, such as read-only memory (ROM), phase change memory (PCM), self-selecting memory, other chalcogenide-based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide-based RRAM (OxRAM), negative- or (NOR) flash memory, and electrically erasable programmable read-only memory (EEPROM).

A memory sub-system controller 115 (or controller 115 for simplicity) can communicate with the memory devices 130, 140 to perform operations such as reading data, writing data, or erasing data (e.g., performing GC operations) at the memory devices 130, 140 and other such operations. The memory sub-system controller 115 can include hardware such as one or more integrated circuits and/or discrete components, a buffer memory, or a combination thereof. The hardware can include digital circuitry with dedicated (e.g., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processor (processing device) 117 configured to execute instructions stored in local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some examples, the local memory 119 can include memory registers storing memory pointers, fetched data, and so forth. The local memory 119 can also include ROM for storing micro-code. While the example memory sub-system 110 in FIG. 1 has been illustrated as including the memory sub-system controller 115, in another example, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory device 130 and/or the memory device 140. The memory sub-system controller 115 can be responsible for other operations such as wear leveling operations, GC operations, error detection and ECC operations, encryption operations, caching operations, and address translations between a logical address (e.g., LBA, namespace) and a physical memory address (e.g., physical block address in a physical address space of the memory device 130 or memory device 140) that are associated with the memory devices 130, 140. The memory sub-system controller 115 can further include host interface circuitry to communicate with the host system 120 via the physical host interface. The host interface circuitry can convert the commands received from the host system 120 into command instructions to access the memory device 130 and/or the memory device 140 as well as convert responses associated with the memory device 130 and/or the memory device 140 into information for the host system 120.

The memory sub-system 110 can also include additional circuitry or components that are not illustrated. In some examples, the memory sub-system 110 can include a cache or buffer (e.g., DRAM) and address circuitry (e.g., a row decoder and a column decoder) that can receive an address from the memory sub-system controller 115 and decode the address to access the memory devices 130, 140.

In some examples, the memory device 130 includes local media controllers 135 that operate in conjunction with memory sub-system controller 115 to execute operations on one or more memory cells of the memory device 130. An external controller (e.g., memory sub-system controller 115) can externally manage the memory device 130 (e.g., perform media management operations on the memory device 130). In some examples, a memory device 130 is a managed memory device, which is a raw memory device combined with a local controller (e.g., local media controller 135) for media management within the same memory device package. An example of a managed memory device is a managed NAND (MNAND) device. Any operation discussed as being performed by the memory sub-system controller 115 can be similarly performed by the local media controllers 135 and vice versa.

The media operations manager 142 can detect incomplete programming across all levels during ALP operations by performing upper page read operations with partial block boundary WL offsets. The media operations manager 142 implements a novel NDPC detection approach that uses default upper page read levels involving three read level strobes to provide increased sensitivity for detecting incomplete programming across multiple threshold voltage levels. Additionally, the media operations manager 142 provides flexibility to add lower page and extra page read operations for further verification and can implement two different PB handling approaches-either using a PB lookup table with boundary WL offsets or applying a low VpassR with specialized boundary WL offsets. This approach effectively addresses the challenges of detecting program completion in ALP operations where all levels are programmed simultaneously using different channel potentials and boosting voltages, rather than the conventional level-by-level programming approach.

Specifically, the media operations manager 142 can determine that a power loss event has occurred during an ALP operation where multiple levels are being programmed simultaneously. In such cases, the media operations manager 142 can perform read operations of an individual portion (e.g., a PB) of the memory device using an individual read level, such as upper page read level (or any other suitable level), to detect incomplete programming. The individual read level can be generated/computed using PB boundary WL offsets and can be any one or combination of the various read levels of the memory device 130. The media operations manager 142 can measure a RBER of the individual read level of the individual portion to determine whether cells (including the cells of the individual read level and other levels, such as upper page, extra page, and/or lower page) in the individual portion have reached their intended threshold voltage levels during the ALP operation. This approach provides increased sensitivity through the use of three read level strobes for upper page reading and offers flexibility to add additional lower page and extra page read operations to verify program completion status. The media operations manager 142 can detect incomplete programming during ALP operations through various approaches. In some implementations, the media operations manager 142 can perform can determine program completion status based on whether the RBER exceeds defined thresholds.

Any discussion with respect to the memory device 130 can similarly be applied to the memory device 140. Any function pertaining to the local media controllers 135 can, in some cases, be performed by the device) memory sub-system controller 115.

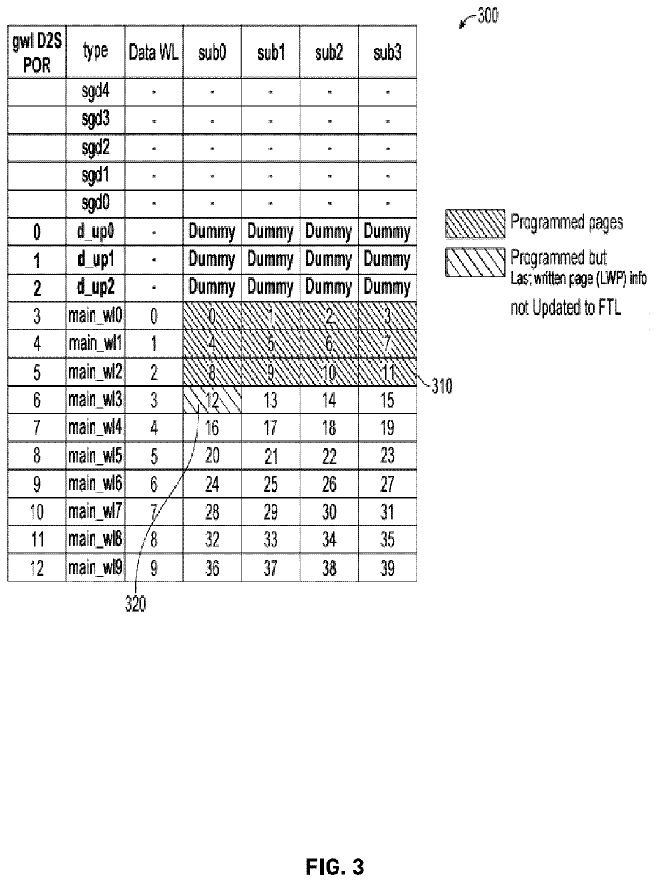

As shown in the diagram 300 of FIG. 3, the media operations manager 142 can store or program data sequentially across SBs of the memory device 130. The media operations manager 142 can maintain a pointer or buffer that identifies what the last programmed portion or LWP is in the memory device 130. Specifically, the media operations manager 142 can store a pointer indicating that the SB3 310 in WL5 is the last programmed portion or page. In such cases, when reading data from the WL5, the media operations manager 142 can determine that the WL5 is a PB that includes the last programmed portion or page based on the data stored in the buffer or pointer. The media operations manager 142 can use the read level offset stored in the boundary WL offset table 230 together with the read level offset stored in the inner WL offset table 220 to read data from the WLG0 (WL5 is in WLG0). In actuality, the pointer or buffer may incorrectly identify the SB3 310 as the last programmed portion because an additional page or portion 320 (e.g., SB0) from the next WL6 may have been programmed before the pointer or buffer was updated to indicate that the portion 320 is the last programmed portion or page. The media operations manager 142 can, in such cases, still consider WL6 to be an empty WL and apply one read level offset to read the data stored in the SB3 310 (e.g., the combined read level offset that includes the offset retrieved from the inner WL offset table 220 and the offset retrieved from the boundary WL offset table 230).

In order to reduce read errors and improve the RBER, the media operations manager 142 can apply an additional offset to reduce (or increase) the read level offset applied to read the data from the boundary WL and/or inner WL. Namely, the media operations manager 142 can dynamically select an additional offset to reduce or increase the read level offset that is used to read data from a WL that is indicated by the pointer or buffer to contain or include the last programmed portion.

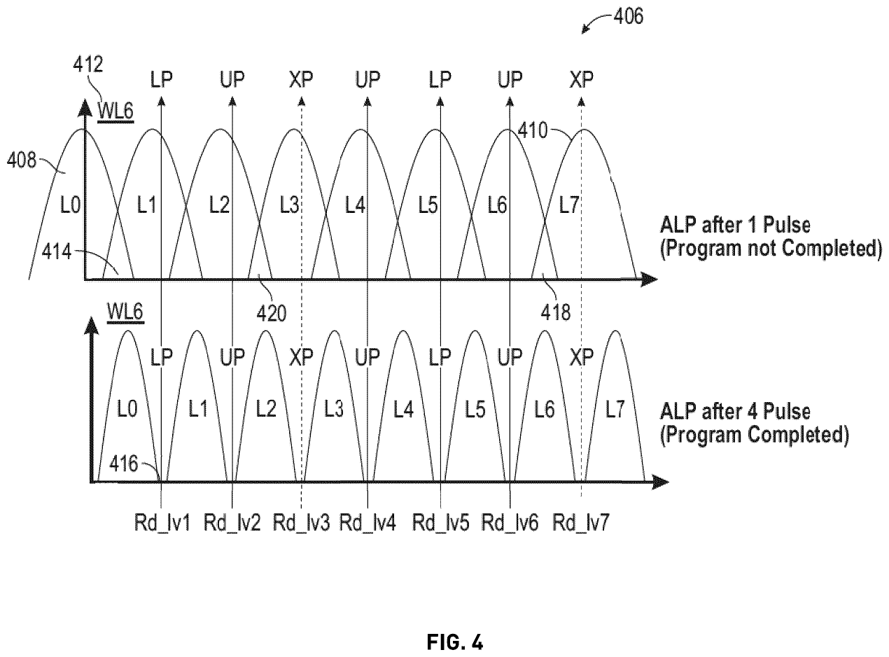

FIG. 4 illustrates memory levels during an ALP sequence 406 sequence, in accordance with some examples. Specifically, FIG. 4 shows ALP sequence 406 that demonstrates how multiple threshold voltage levels are programmed simultaneously during the ALP operations, contrasting the results of the cell level peaks and valleys after initial programming and after completion.

In the first phase of ALP programming, the media operations manager 142 applies a single program pulse and simultaneously programs the memory cells from the first level 408 through the last level 410 on an individual WL 412. When programming memory blocks, some blocks may be only PB with certain WL remaining empty, while others are fully programmed. The LWP in a PB may require special handling during read operations and/or during NDPC operations. During this initial programming pulse, a same voltage is applied to all of the gates of the cells across all the levels (e.g., L0-L7) reach approximate target positions across all levels simultaneously, but the threshold voltage distributions (where data is ideally read in the valleys between the peaks) are initially distorted. For example, data associated with read level 0 is shown by the distorted level 414 as being distorted with level 1. Namely, the cell distribution for level 0 overlaps partially with the cell distribution from level 1 which distorts information that is meant to be read between those distributions to access the set of data associated with level 0 or level 0. This occurs because ALP applies different bit line biases to achieve varying boosting potentials for each level within a single programming pulse. Similarly, the UP cell distribution overlaps the XP cell distribution resulting in the XP read level 420 and UP read level 418 being distorted.

After additional programming pulses (e.g., four programming pulses) are applied to the individual WL 412, the same individual WL 412 can fine tune the cell level distributions to remove any distortion between the levels. For PBs, the media operations manager 142 may need to track which WL contains the LWP to properly apply boundary WL offsets during subsequent read operations, such as when performing the NDPC operations. For example, a lower voltage (than that which was applied to the gates in the first phase) is applied to the channel to create a voltage potential difference at each cell level. This results in the threshold voltage distributions being at fine-tuned levels 416 to their final positions. This fine-tuning process uses verify operations to tighten the threshold voltage distributions for each level, resulting in well-defined voltage states for reliable data storage. As shown, now the cell distributions of level 0 no longer overlaps the cell distribution of level 1 which enables data read between those distributions to be properly read with minimal errors.

The ALP operation represents a fundamental advancement in memory programming by implementing simultaneous programming across multiple threshold voltage levels. Unlike traditional ISPP approaches that program levels sequentially, ALP applies different channel potentials to different memory cells to achieve varying voltage differentials between the gate voltage and respective channel potentials, enabling concurrent programming of all levels. The core mechanism of ALP relies on applying different bit line biases to achieve different boosting potentials (Vpillar) for each memory cell. This approach allows the media operations manager 142 to simultaneously program cells to their target threshold voltages using a single program voltage pulse while controlling individual channel potentials. The efficiency of this method is demonstrated by requiring only 4-6 pulses to complete programming, compared to ISPP's 10-15 pulses.

During the initial programming phase, ALP applies a single program pulse that simultaneously programs memory cells from the first level through the last level on an individual word line. This process uses different channel potentials and a single gate bias voltage to achieve approximate target positions across all levels simultaneously. The varying channel potentials are achieved through different bit line biases, creating distinct boosting potentials for each level. The simultaneous programming nature of ALP creates a unique initial state where cell distributions may overlap between adjacent levels temporarily during programming. For example, when programming begins, data associated with one level may show distortion with adjacent levels, as demonstrated by the overlapping cell distributions that initially occur. This overlap is a natural consequence of the simultaneous programming approach and requires subsequent fine-tuning.

To address the initial overlapping distributions, ALP implements a fine-tuning process that uses subsequent programming pulses to tighten the threshold voltage distributions for each level. This process applies a lower voltage to the channel to create precise voltage potential differences at each cell level, resulting in well-defined voltage states that ensure reliable data storage. The effectiveness of ALP's programming mechanism becomes particularly evident when considering power loss scenarios. Since all levels are programmed simultaneously using different channel potentials and a single gate bias voltage, a power loss during programming means cells across all levels may not have reached their intended threshold voltages. This differs significantly from traditional ISPP approaches where only the highest levels would typically be affected by power loss.

The programming mechanism includes verify operations that are used for ensuring proper threshold voltage distributions. These operations help tighten the distributions for each programming level, creating distinct valleys between peaks that enable reliable read operations. The verify operations are particularly important given the simultaneous nature of the programming, as they ensure proper separation between adjacent voltage levels. ALP's programming approach may require specialized handling of PBs, particularly when dealing with boundary WLs. The media operations manager 142 may need to maintain precise control over the channel potentials and boosting voltages while accounting for the presence of empty WL and LWPs, ensuring consistent programming across all cells. The simultaneous programming mechanism of ALP necessitates a sophisticated approach to detecting program completion. Since all levels are programmed concurrently with varying channel voltages, the media operations manager 142 needs to be capable of verifying proper programming across multiple threshold voltage levels simultaneously, rather than checking levels sequentially as in traditional approaches.

The programming mechanism's effectiveness is validated through RBER measurements, which can indicate whether cells have reached their intended threshold voltages across multiple levels. This is particularly important given the simultaneous nature of the programming, as distortion or incomplete programming can affect all levels rather than just the highest level as in traditional approaches.

For example, during the first phase of ALP programming, when the single program pulse is applied to simultaneously program memory cells across all levels, an APL event can occur that interrupts the programming sequence. When this happens, the distorted threshold voltage distributions remain in their incomplete state, with cell distributions overlapping between adjacent levels. This creates a situation where the data meant to be read between those distributions becomes unreliable due to the overlapping cell distributions.

The novel NDPC approach addresses this scenario by enabling detection of incomplete programming using any read level, not just the UP read level. This is important because in ALP operations, all levels are programmed simultaneously using different channel potentials and a single gate bias voltage. Therefore, when a power loss occurs, cells across all levels may be left in partially programmed states. The media operations manager 142 can perform read operations using default read levels with PB boundary WL offsets to detect the incomplete programming. Since the distortion exists across all levels due to the simultaneous programming nature of ALP, any read level can effectively indicate whether the programming was completed or incomplete before the power loss occurred.

The media operations manager 142 provides flexibility to use various read levels for detection, including lower page, upper page, and extra page read levels. This multi-level detection capability is particularly important because the distortion patterns in ALP differ fundamentally from traditional ISPP programming, where only the highest levels would typically be affected by power loss. When performing the NDPC process, the media operations manager 142 can measure RBER at any selected read level. If the measured RBER exceeds or transgresses a threshold, the media operations manager 142 determines that the cells have not reached their intended threshold voltages across multiple levels due to the interrupted programming sequence.

The media operations manager 142 can implement different approaches for handling partial blocks during the detection process. The media operations manager 142 can either use a PB lookup table with boundary WL offsets (as discussed previously in connection with FIG. 2 and FIG. 3) or apply a low VpassR with specialized boundary WL offsets, providing flexibility in how the incomplete programming is detected. For increased detection sensitivity, the media operations manager 142 can perform multiple read operations using different read levels and combining the results. This approach takes advantage of the fact that distortion exists across all levels, allowing for more robust detection of incomplete programming compared to conventional NDPC methods that focus only on specific levels.

The media operations manager 142 can also adjust read levels to increase detection sensitivity based on the specific characteristics of the distorted distributions. This adaptability is important because the distortion patterns can vary depending on when the power loss occurred during the programming sequence. The media operations manager 142 maintains flexibility to add additional read operations on lower pages and extra pages to further verify program completion status. This comprehensive approach ensures reliable detection of incomplete programming across all levels, addressing the unique challenges posed by ALP's simultaneous multi-level programming method.

By enabling detection using any read level, the media operations manager 142 effectively addresses the fundamental difference between ALP and traditional ISPP programming, where power loss affects all levels simultaneously rather than just the highest levels. This makes the NDPC process more robust and better suited for detecting incomplete programming in ALP operations.

The NDPC detection process for ALP operations can employ three distinct read level strobes specifically designed for upper page reading. This approach provides increased sensitivity for detecting incomplete programming across multiple threshold voltage levels compared to conventional single-strobe methods. The media operations manager 142 can implement default upper page read levels with these three strobes to effectively capture distortion patterns that may occur when programming is interrupted.

The detection sensitivity improvements can be achieved through specialized handling of PBs, where the media operations manager 142 can either use a PB lookup table with boundary WL offsets or apply a low VpassR with specialized boundary WL offsets. This dual approach provides flexibility in detection while maintaining high sensitivity across all programming levels. The decision to add lower page and extra page read operations can be based on the initial upper page read results. When the media operations manager 142 detects potential distortion patterns in the upper page reads (e.g., in response to determining that the RBER associated with data read from the UP transgresses a threshold), the media operations manager 142 can initiate additional read operations on lower pages and extra pages to verify program completion status. Namely, rather than immediately triggering operations to correct for the incomplete programming based on data read from the UP, the media operations manager 142 can first test the data on the LP and/or XP before triggering such operations. This multi-level verification approach provides comprehensive coverage across all programming levels, ensuring reliable detection of incomplete programming.

The selection between PB lookup table and low VpassR approaches can be determined by the specific characteristics of the PB being analyzed. For PBs with multiple WLs, the media operations manager 142 can apply a low pass read voltage to empty WLs while using modified boundary WL offset tables specifically configured for the low pass read voltage scenario. Alternatively, the media operations manager 142 may utilize separate inner and boundary WL offset tables, storing different sets of read level offsets for different WL types. The boundary WL offset parameters can be managed through two distinct approaches. In the PB lookup table approach, the media operations manager 142 maintains separate tables for inner and boundary WL offsets, allowing for precise control of read levels. For the low VpassR approach, the media operations manager 142 applies specialized boundary WL offsets specifically optimized for the reduced pass read voltage conditions.

When operating in low VpassR mode, the media operations manager 142 modifies boundary WL offsets by combining offsets from different tables-using one offset for inner WL and generating combined offsets for boundary WLs. This approach enables effective handling of partially programmed blocks while maintaining optimal read conditions for both programmed and unprogrammed regions. The determination of incomplete programming relies on measuring the RBER of the individual read level of the individual portion to evaluate whether cells have reached their intended threshold voltage levels during the ALP operation. When the measured RBER exceeds defined thresholds, it indicates that the programming sequence was interrupted before completion.

The correlation between RBER measurements and programming completion status is particularly relevant in ALP operations because when power loss occurs during programming, all levels are potentially incomplete or distorted, not just the highest level. Since ALP programs all levels simultaneously using different channel potentials and a single gate bias voltage, a power loss during programming means cells across all levels may not have reached their intended threshold voltages. The detection of power loss events during ALP operations may rely on specialized monitoring of programming status across multiple levels simultaneously. Unlike conventional ISPP approaches where power loss primarily affects the highest levels, ALP operations require comprehensive monitoring across all programming levels due to the simultaneous programming nature.

The programming status after power loss can be evaluated through read operations using specific read levels to identify incomplete programming. The media operations manager 142 can perform read operations of an individual portion of the memory device 130 using an individual read level to detect incomplete programming. This approach allows for detection of distortion across multiple levels when power loss occurs before programming completes. The initiation of the NDPC process after power loss detection follows specific criteria based on the detection of potential programming interruptions. The media operations manager 142 can implement a comprehensive NDPC process specifically designed to verify programming completion status after power loss events in 3D NAND devices, with the flexibility to adapt its approach based on whether PB handling uses lookup tables or low VpassR mode.

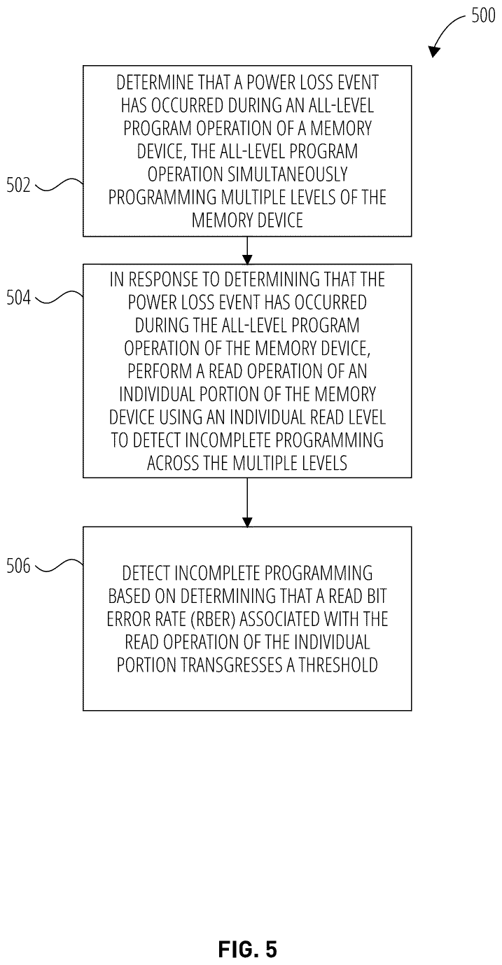

FIG. 5 illustrates a diagram 500 of operations performed using the media operations manager 142, in accordance with some examples. The method or process of diagram 500 can be performed by processing logic that can include hardware (e.g., a processing device, circuitry, dedicated logic, programmable logic, microcode, hardware of a device, an integrated circuit, etc.), software (e.g., instructions run or executed on a processing device), or a combination thereof. In some examples, the method or process of diagram 500 is performed by the memory sub-system controller 115, local media controllers 135, and/or subcomponents of the memory sub-system controller 115 and/or local media controllers 135 of FIG. 1. In these examples, the method or process of diagram 500 can be performed, at least in part, by the media operations manager 142. Although the processes are shown in a particular sequence or order, unless otherwise specified, the order of the processes can be modified. Thus, the illustrated examples should be understood only as examples; the illustrated processes can be performed in a different order, and some processes can be performed in parallel. Additionally, one or more processes can be omitted in various examples. Thus, not all processes are required in every example, other process flows are possible.

Referring now to FIG. 5, the method begins at operation 502 with the media operations manager 142 determining that a power loss event has occurred during an ALP operation of a memory device 130, the ALP operation simultaneously programming multiple levels of the memory device 130. At operation 504, the media operations manager 142, in response to determining that the power loss event has occurred during the ALP operation of the memory device 130, performs a read operation of an individual portion of the memory device 130 using an individual read level to detect incomplete programming across the multiple levels. At operation 506, the media operations manager 142 detects incomplete programming based on determining that a RBER associated with the read operation of the individual portion transgresses a threshold.

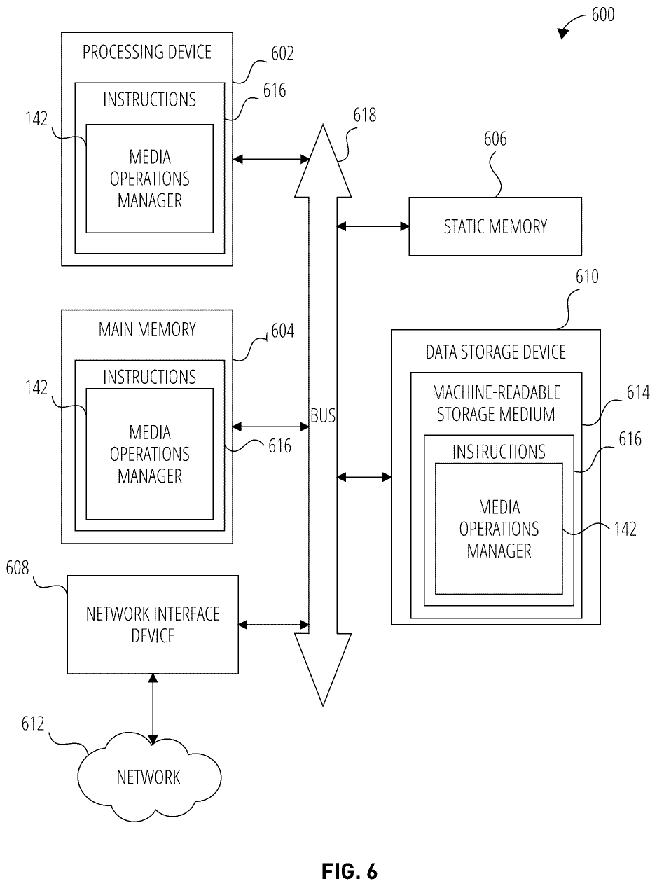

FIG. 6 illustrates an example machine in the form of a computer system 600 within which a set of instructions can be executed for causing the machine to perform any one or more of the methodologies discussed herein. In some examples, the computer system 600 can correspond to a host system (e.g., the host system 120 of FIG. 1) that includes, is coupled to, or utilizes a memory sub-system (e.g., the memory sub-system 110 of FIG. 1) or can be used to perform the operations described herein. In alternative examples, the machine can be connected (e.g., networked) to other machines in a local area network (LAN), an intranet, an extranet, and/or the Internet. The machine can operate in the capacity of a server or a client machine in a client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 600 includes a processing device 602, a main memory 604 (e.g., ROM, flash memory, DRAM such as SDRAM or Rambus DRAM (RDRAM), etc.), a static memory 606 (e.g., flash memory, static random access memory (SRAM), etc.), and a data storage device 610, which communicate with each other via a bus 618.

The processing device 602 represents one or more general-purpose processing devices such as a microprocessor, a central processing unit, or the like. More particularly, the processing device 602 can be a complex instruction set computing (CISC) microprocessor, a reduced instruction set computing (RISC) microprocessor, a very long instruction word (VLIW) microprocessor, a processor implementing other instruction sets, or processors implementing a combination of instruction sets. The processing device 602 can also be one or more special-purpose processing devices such as an application-specific integrated circuit (ASIC), a field programmable gate array (FPGA), a digital signal processor (DSP), a network processor, or the like. The processing device 602 is configured to execute instructions 616 for performing the operations and steps discussed herein. The computer system 600 can further include a network interface device 608 to communicate over a network 612.

The data storage device 610 can include a machine-readable storage medium 614 (also known as a computer-readable medium) on which is stored one or more sets of instructions 616 or software embodying any one or more of the methodologies or functions described herein. The instructions 616 can also reside, completely or at least partially, within the main memory 604 and/or within the processing device 602 during execution thereof by the computer system 600, the main memory 604 and the processing device 602 also constituting machine-readable storage media. The machine-readable storage medium 614, data storage device 610, and/or main memory 604 can correspond to the memory sub-system 110 of FIG. 1.

In one example, the instructions 616 include instructions to implement functionality corresponding to providing block failure protection for a zone memory sub-system as described herein (e.g., the REH component 113 of FIG. 1). While the machine-readable storage medium 614 is shown in an example to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Described implementations of the subject matter can include one or more features, alone or in combination as illustrated below by way of examples.

### Example 1

A system comprising: a memory device; and a processing device, operatively coupled to the memory device, configured to perform operations comprising: determining that a power loss event has occurred during an all-level program operation of the memory device, the all-level program operation simultaneously programming multiple levels of the memory device; in response to determining that the power loss event has occurred during the all-level program operation of the memory device, performing a read operation of an individual portion of the memory device using an individual read level to detect incomplete programming across the multiple levels; and detecting incomplete programming based on determining that a read bit error rate (RBER) associated with the read operation of the individual portion transgresses a threshold.

### Example 2

The system of Example 1, wherein the all-level program operation comprises: applying different channel potentials to different cells of the memory device to achieve different voltage differentials between a gate voltage and respective channel potentials; and using verify operations to reduce threshold voltage distributions for each level of the multiple levels.

### Example 3

The system of any one of Examples 1-2, wherein the individual portion comprises a last written page, wherein the individual read level comprises an upper page read level, and wherein the RBER indicates distortion across the multiple levels due to the power loss event occurring before completion of the all-level program operation.

### Example 4

The system of any one of Examples 1-3, the memory device comprising at least one of a multi-level cell (MLC) memory device, a tri-level cell (TLC) memory device, or quad-level cell (QLC) memory device.

### Example 5

The system of any one of Examples 1-4, the power loss event comprising an asynchronous power loss (APL).

### Example 6

The system of any one of Examples 1-5, wherein the individual portion comprises a partially programmed block (PB) comprising a plurality of word lines (WLs), the plurality of WLs comprising one or more inner WLs and a boundary WL, the operations further comprising: applying a low pass read voltage to empty WLs of the PB; and using a modified boundary WL offset table configured for the low pass read voltage to perform the read operation on the individual portion.

### Example 7

The system of any one of Examples 1-6, wherein the individual portion comprises a partially programmed block (PB) comprising a plurality of word lines (WLs), the plurality of WLs comprising one or more inner WLs and a boundary WL, wherein an individual WL offset table comprises an inner WL offset table, the operations comprising obtaining the individual read level using a boundary WL offset table.

### Example 8

The system of Example 7, the operations comprising: storing the inner WL offset table comprising a first plurality of read level offsets; and storing the boundary WL offset table comprising a second plurality of read level offsets, the boundary WL offset table representing a set of read level offsets for reading data from one or more WLs of the PB comprising a last written page.

### Example 9

The system of Example 8, the operations comprising: reading a first set of data from the one or more inner WLs of the individual portion using a first read level offset retrieved from the inner WL offset table; and reading a second set of data from the boundary WL of the individual portion using a combined read level offset generated based on the first read level offset and a second read level offset retrieved from the boundary WL offset table.

### Example 10

The system of Example 9, the operations comprising: adding the first read level offset and the second read level offset to generate the combined read level offset.

### Example 11

The system of any one of Examples 9-10, the operations comprising: retrieving a read threshold voltage for reading data from the individual portion; modifying the read threshold voltage by the first read level offset to read a first set of data; and modifying the read threshold voltage by the combined read level offset to read a second set of data.

### Example 12

The system of any one of Examples 1-11, the operations comprising: maintaining a buffer that identifies which region of the memory device has been programmed last; determining that the individual portion comprises the region of the memory device that has been programmed last; and determining that the individual portion corresponds to a partially programmed block (PB) in response to determining that the individual portion comprises the region of the memory device that has been programmed last.

### Example 13

The system of any one of Examples 1-12, the operations further comprising: performing additional read operations of at least one of a lower page or an extra page to further verify program completion status; and adjusting read levels for the lower page, upper page, or extra page to increase detection sensitivity.

### Example 14

The system of any one of Examples 1-13, the operations further comprising: determining whether a partial block lookup table or low VpassR mode is being used for partially programmed block (PB) handling; and selecting between applying a partial block boundary word line (WL) offset or a low VpassR boundary WL offset based on determining whether the partial block lookup table or low VpassR mode is being used for PB handling.

### Example 15

The system of any one of Examples 1-14, wherein the read operation is performed as part of a NAND Detect Program Completion (NDPC) process, the NDPC process comprising a sequence of operations used to check if a last written page has completed programming when a power loss event occurs.

### Example 16

The system of any one of Examples 1-15, wherein the memory device comprises a three-dimensional (3D) NAND device, the individual read level being selected from any one of the multiple levels of the memory device.

### Example 17

At least one non-transitory machine-readable storage medium comprising instructions that, when executed by a processing device, cause the processing device to perform operations comprising: determining that a power loss event has occurred during an all-level program operation of a memory device, the all-level program operation simultaneously programming multiple levels of the memory device; in response to determining that the power loss event has occurred during the all-level program operation of the memory device, performing a read operation of an individual portion of the memory device using an individual read level to detect incomplete programming across the multiple levels; and detecting incomplete programming based on determining that a read bit error rate (RBER) associated with the read operation of the individual portion transgresses a threshold.

### Example 18

A method comprising: determining that a power loss event has occurred during an all-level program operation of a memory device, the all-level program operation simultaneously programming multiple levels of the memory device; in response to determining that the power loss event has occurred during the all-level program operation of the memory device, performing a read operation of an individual portion of the memory device using an individual read level to detect incomplete programming across the multiple levels; and detecting incomplete programming based on determining that a read bit error rate (RBER) associated with the read operation of the individual portion transgresses a threshold.

### Example 19

The method of Example 18, wherein the all-level program operation comprises: applying different channel potentials to different cells of the memory device to achieve different voltage differentials between a gate voltage and respective channel potentials; and using verify operations to reduce threshold voltage distributions for each level of the multiple levels.

### Example 20

The method of any one of Examples 18-19, wherein the individual portion comprises a last written page, wherein the individual read level comprises an upper page read level, and wherein the RBER indicates distortion across the multiple levels due to the power loss event occurring before completion of the all-level program operation.

The term “coupled with” generally refers to a connection between components, which can be an indirect communicative connection or direct communicative connection (e.g., without intervening components), whether wired or wireless, including connections such as electrical, optical, magnetic, and the like.

“System data” hereinafter refers to data that is created and/or maintained by the memory sub-system for performing operations in response to host requests and for media management.

“User data” hereinafter generally refers to host data and garbage collection data.

“Read disturb” refers to a phenomenon where repeated read operations on a specific WL in a NAND flash memory block cause unintended changes in the threshold voltages of adjacent cells on unselected WLs within the same block. This effect can potentially lead to data corruption in neighboring cells if left unmanaged, necessitating periodic data refresh or block relocation (folding) operations to maintain data integrity in NAND-based storage devices.

“Slow charge loss (SCL)” refers to charge retention loss or data retention loss that occurs in flash memory cells over time. SCL refers to the gradual leakage of electrical charge from the floating gate of a NAND cell, which can lead to data corruption or loss if left unchecked. This SCL is a natural aging process in flash memory and becomes more pronounced as the memory cells undergo more program/erase cycles and as the manufacturing process shrinks to smaller geometries. The rate of charge loss can be affected by factors such as temperature, the quality of the insulating oxide layer, and the overall design of the memory cell.

“Partially programmed block (PB)” refers to memory blocks that are not fully programmed and remain open with one or more sub-blocks that are empty and ready to be programmed. This is in contrast to full blocks (FBs) which are memory blocks that are fully programmed and closed. PBs require special handling for read operations, including the application of different read level offsets for inner word lines (WLs) and boundary WLs to reduce read disturb errors and other extrinsic defect related errors when reading data from these blocks.

“Inner WL” refers to any WL in a PB that does not contain the last written page. Inner WLs may require specific read level offsets retrieved from an inner WL offset table to reduce read disturb errors and other extrinsic defect related errors when reading data.

“Boundary WL” refers to the WL in a PB that contains the last written page. Boundary WLs may require special handling during read operations where both the inner WL offset and a modified boundary WL offset are combined to generate the read level offset used to read data, in order to reduce RBER associated with reading the last programmed portion.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer-readable storage medium, such as, but not limited to, any type of disk including floppy disks, optical disks, CD-ROMs, and magnetic-optical disks, ROMs, RAMs, EPROMs, EEPROMs, magnetic or optical cards, or any type of media suitable for storing electronic instructions, each coupled to a computer system bus.

The algorithms and displays presented herein are not inherently related to any particular computer or other apparatus. Various general-purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium (such as a non-transitory machine-readable medium) having stored thereon instructions, which can be used to program a computer system (or other electronic devices) to perform a process according to the present disclosure. A machine-readable medium includes any mechanism for storing information in a form readable by a machine (e.g., a computer). In some examples, a machine-readable (e.g., computer-readable) medium includes a machine (e.g., a computer) readable storage medium such as a ROM, RAM, magnetic disk storage media, optical storage media, flash memory components, and so forth. A machine-readable storage medium can be non-transitory (in other words, not having any transitory signals) in that it does not embody a propagating signal. However, labeling a machine-readable storage medium “non-transitory” should not be construed to mean that the machine-readable storage medium is incapable of movement; the machine-readable storage medium should be considered as being transportable from one physical location to another.

In the foregoing specification, examples of the disclosure have been described with reference to specific examples thereof. It will be evident that various modifications can be made thereto without departing from the broader scope of examples of the disclosure as set forth in the following claims. The specification and drawings are, accordingly, to be regarded in an illustrative sense rather than a restrictive sense.

1. A system comprising:
a memory device; and
a processing device, operatively coupled to the memory device, configured to perform operations comprising:
determining that a power loss event has occurred during an all-level program operation of the memory device, the all-level program operation simultaneously programming multiple levels of the memory device;
in response to determining that the power loss event has occurred during the all-level program operation of the memory device, performing a read operation of an individual portion of the memory device using an individual read level to detect incomplete programming across the multiple levels; and
detecting incomplete programming based on determining that a read bit error rate (RBER) associated with the read operation of the individual portion transgresses a threshold.

2. The system of claim 1, wherein the all-level program operation comprises:
applying different channel potentials to different cells of the memory device to achieve different voltage differentials between a gate voltage and respective channel potentials; and
using verify operations to reduce threshold voltage distributions for each level of the multiple levels.

3. The system of claim 1, wherein the individual portion comprises a last written page (LWP), wherein the individual read level comprises an upper page read level, and wherein the RBER indicates distortion across the multiple levels due to the power loss event occurring before completion of the all-level program operation.

4. The system of claim 1, the memory device comprising at least one of a multi-level cell (MLC) memory device, a tri-level cell (TLC) memory device, or quad-level cell (QLC) memory device.

5. The system of claim 1, the power loss event comprising an asynchronous power loss (APL).

6. The system of claim 1, wherein the individual portion comprises a partially programmed block (PB) comprising a plurality of word lines (WLs), the plurality of WLs comprising one or more inner WLs and a boundary WL, the operations further comprising:
applying a low pass read voltage to empty WLs of the PB; and
using a modified boundary WL offset table configured for the low pass read voltage to perform the read operation on the individual portion.

7. The system of claim 1, wherein the individual portion comprises a partially programmed block (PB) comprising a plurality of word lines (WLs), the plurality of WLs comprising one or more inner WLs and a boundary WL, wherein an individual WL offset table comprises an inner WL offset table, the operations comprising:
obtaining the individual read level using a boundary WL offset table.

8. The system of claim 7, the operations comprising:
storing the inner WL offset table comprising a first plurality of read level offsets; and
storing the boundary WL offset table comprising a second plurality of read level offsets, the boundary WL offset table representing a set of read level offsets for reading data from one or more WLs of the PB comprising a last written page (LWP).

9. The system of claim 8, the operations comprising:
reading a first set of data from the one or more inner WLs of the individual portion using a first read level offset retrieved from the inner WL offset table; and
reading a second set of data from the boundary WL of the individual portion using a combined read level offset generated based on the first read level offset and a second read level offset retrieved from the boundary WL offset table.

10. The system of claim 9, the operations comprising:
adding the first read level offset and the second read level offset to generate the combined read level offset.

11. The system of claim 9, the operations comprising:
retrieving a read threshold voltage for reading data from the individual portion;
modifying the read threshold voltage by the first read level offset to read a first set of data; and
modifying the read threshold voltage by the combined read level offset to read a second set of data.

12. The system of claim 1, the operations comprising:
maintaining a buffer that identifies which region of the memory device has been programmed last;
determining that the individual portion comprises the region of the memory device that has been programmed last; and
determining that the individual portion corresponds to a partially programmed block (PB) in response to determining that the individual portion comprises the region of the memory device that has been programmed last.

13. The system of claim 1, the operations further comprising:
performing additional read operations of at least one of a lower page or an extra page to further verify program completion status; and
adjusting read levels for the lower page, upper page, or extra page to increase detection sensitivity.

14. The system of claim 1, the operations further comprising:
determining whether a partial block lookup table or low VpassR mode is being used for partially programmed block (PB) handling; and
selecting between applying a partial block boundary word line (WL) offset or a low VpassR boundary WL offset based on determining whether the partial block lookup table or low VpassR mode is being used for PB handling.

15. The system of claim 1, wherein the read operation is performed as part of a NAND Detect Program Completion (NDPC) process, the NDPC process comprising a sequence of operations used to check if a last written page (LWP) has completed programming when a power loss event occurs.

16. The system of claim 1, wherein the memory device comprises a three-dimensional (3D) NAND device, the individual read level being selected from any one of the multiple levels of the memory device.

17. At least one non-transitory machine-readable storage medium comprising instructions that, when executed by a processing device, cause the processing device to perform operations comprising:
determining that a power loss event has occurred during an all-level program operation of a memory device, the all-level program operation simultaneously programming multiple levels of the memory device;
in response to determining that the power loss event has occurred during the all-level program operation of the memory device, performing a read operation of an individual portion of the memory device using an individual read level to detect incomplete programming across the multiple levels; and
detecting incomplete programming based on determining that a read bit error rate (RBER) associated with the read operation of the individual portion transgresses a threshold.

18. A method comprising:
determining that a power loss event has occurred during an all-level program operation of a memory device, the all-level program operation simultaneously programming multiple levels of the memory device;
in response to determining that the power loss event has occurred during the all-level program operation of the memory device, performing a read operation of an individual portion of the memory device using an individual read level to detect incomplete programming across the multiple levels; and
detecting incomplete programming based on determining that a read bit error rate (RBER) associated with the read operation of the individual portion transgresses a threshold.

19. The method of claim 18, wherein the all-level program operation comprises:
applying different channel potentials to different cells of the memory device to achieve different voltage differentials between a gate voltage and respective channel potentials; and
using verify operations to reduce threshold voltage distributions for each level of the multiple levels.

20. The method of claim 18, wherein the individual portion comprises a last written page, wherein the individual read level comprises an upper page read level, and wherein the RBER indicates distortion across the multiple levels due to the power loss event occurring before completion of the all-level program operation.
